(19) United States
(12) Patent Application Publication
(10) Pub. No.: US 2018/0017603 A1
(43) Pub. Date: Jan. 18, 2018

(54) OSCILLATION DEVICE, COMPUTING DEVICE, AND MEASUREMENT METHOD

(71) Applicant: KABUSHIKI KAISHA TOSHIBA, Tokyo (JP)

(72) Inventor: Hayato GOTO, Kawasaki (JP)

(73) Assignee: KABUSHIKI KAISHA TOSHIBA, Tokyo (JP)

(21) Appl. No.: 15/429,838

(22) Filed: Feb. 10, 2017

(30) Foreign Application Priority Data
Jul. 15, 2016 (JP) 2016-140498

(51) Int. Cl. G01R 23/02; H01P 7/08; H01L 39/02

(52) U.S. Cl. CPC G01R 23/02; H01L 39/025; H01P 7/08

(57) ABSTRACT

According to one embodiment, an oscillation device includes a resonator, an electromagnetic wave application portion, a filter, and a conductive portion. The resonator includes a Josephson junction. The electromagnetic wave application portion applies a first electromagnetic wave and a second electromagnetic wave to the resonator. The first electromagnetic wave has a component of a first frequency. The second electromagnetic wave has a component of the first frequency and a component of a second frequency. The conductive portion transmits an electromagnetic wave passing through the filter. The resonator oscillates at a third frequency due to the first electromagnetic wave and oscillates at the third frequency and a fourth frequency due to the second electromagnetic wave. A transmittance of the filter for the fourth frequency is higher than a transmittance of the filter for the third frequency.

### CROSS-REFERENCE TO RELATED APPLICATIONS

This application is based upon and claims the benefit of priority from Japanese Patent Application No. 2016-140498, filed on Jul. 15, 2016; the entire contents of which are incorporated herein by reference.

### FIELD

Embodiments described herein relate generally to an oscillation device, a computing device and a measurement method.

### BACKGROUND

A computer that utilizes an oscillation device having a quantum-mechanical bifurcation phenomenon has been proposed. It is desirable to be able to adjust the loss in such an oscillation device.

### BRIEF DESCRIPTION OF THE DRAWINGS

FIG. 1 is a schematic view illustrating an oscillation device according to an embodiment;

FIG. 2 is a plan view illustrating a portion of the oscillation device according to the embodiment;

FIG. 3 is a graph illustrating the frequency characteristics of the filter of the oscillation device according to the embodiment;

FIG. 4 is a graph illustrating calculation results of the Kerr coefficient and the parametric excitation amplitude of the first example;

FIG. 5 is a graph illustrating calculation results of the resonant frequencies of the higher order modes of the first example;

FIG. 6 is a graph illustrating calculation results of the coupling coefficient of the fundamental mode and the first-order mode of the first example;

FIG. 7 is a graph illustrating calculation results of the Kerr coefficient and the parametric excitation amplitude of the second example;

FIG. 8 is a graph illustrating calculation results of the resonant frequencies of the higher order modes of the second example;

FIG. 9 is a graph illustrating calculation results of the coupling coefficient of the fundamental mode and the first-order mode of the second example; and

FIG. 10 is a schematic view illustrating a computing device according to the embodiment.

### DETAILED DESCRIPTION

According to one embodiment, an oscillation device includes a resonator, an electromagnetic wave application portion, a filter, and a conductive portion. The resonator includes a Josephson junction. The electromagnetic wave application portion applies a first electromagnetic wave and a second electromagnetic wave to the resonator. The first electromagnetic wave has a component of a first frequency. The second electromagnetic wave has a component of the first frequency and a component of a second frequency. The conductive portion transmits an electromagnetic wave passing through the filter. The resonator oscillates at a third frequency due to the first electromagnetic wave and oscillates at the third frequency and a fourth frequency due to the second electromagnetic wave. A transmittance of the filter for the fourth frequency is higher than a transmittance of the filter for the third frequency.

According to one embodiment, a measurement method of an oscillation state of a resonator is disclosed. The resonator includes a loop including a Josephson junction. The resonator oscillates at a second frequency by modulating flux inside the loop at a first frequency. The second frequency is equal to a half value of the first frequency. The method includes causing the resonator to oscillate at a fourth frequency by applying a modulation at a third frequency to the flux of the loop in addition to the modulation at the first frequency. The fourth frequency is equal to the sum of the second frequency and the third frequency. The method includes extracting, to a read line, an electromagnetic wave of the fourth frequency via a filter transmitting the electromagnetic wave of the fourth frequency. The method includes measuring the electromagnetic wave of the fourth frequency in the read line.

According to one embodiment, a measurement method of an oscillation state of a resonator is disclosed. The resonator includes a Josephson junction. The method includes applying, to the resonator, a first electromagnetic wave having a component of a first frequency. The method includes applying a second electromagnetic wave to the resonator. The second electromagnetic wave has a component of the first frequency and a component of a second frequency. The method includes measuring an electromagnetic wave transmitted via a filter from the resonator. The resonator oscillates at a third frequency due to the first electromagnetic wave and oscillates at the third frequency and a fourth resonant frequency due to the second electromagnetic wave. The transmittance of the filter for the fourth frequency is higher than a transmittance of the filter for the third frequency.

Various embodiments will be described hereinafter with reference to the accompanying drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

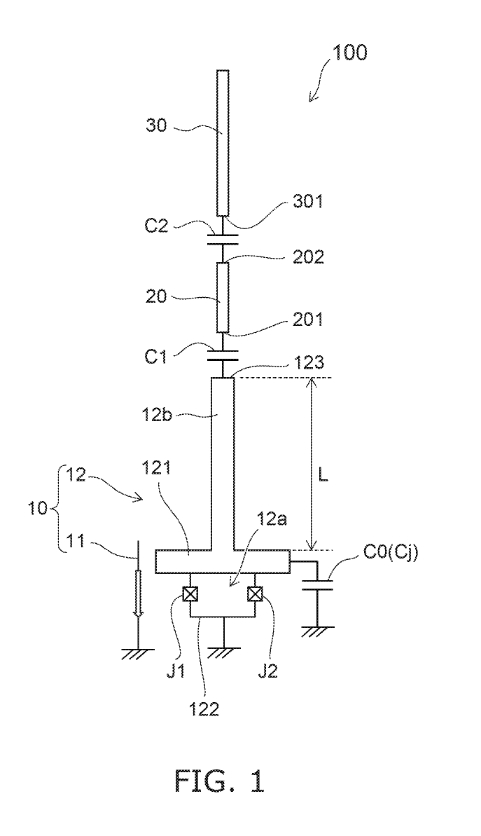

FIG. 1 is a schematic view illustrating an oscillation device according to an embodiment.

FIG. 1 schematically illustrates a portion of the oscillation device 100 according to the embodiment by using a circuit diagram.

As illustrated in FIG. 1, the oscillation device 100 according to the embodiment includes an oscillator 10, a filter 20, and a conductive portion 30. The oscillator 10 includes an electromagnetic wave application portion 11 and a resonator 12.

The resonator 12 is a superconducting nonlinear resonator including a Josephson junction. The resonator 12 includes a superconducting portion 121 and a superconducting portion 122 that are connected to each other; and the resonator 12 has a dc SQUID (superconducting quantum interference device) structure. In other words, the resonator 12 includes a loop (a ring) 12a provided by the superconducting portions 121 and 122. The superconducting portion 121 and the superconducting portion 122 are connected to each other by Josephson junctions J1 and J2. Specifically, an insulating body is provided between one end of the superconducting portion 121 and one end of the superconducting portion 122; and an insulating body is provided between another end of the superconducting portion 121 and another end of the superconducting portion 122. Thereby, the loop 12a is provided.

For example, the center of the resonator 12 is used as a waveguide 12b having a length L. In other words, the superconducting portion 121 includes the waveguide 12b extending from an end of the loop 12a toward the outer side of the loop 12a. In the example, a capacitor C0 (a capacitance Cj) is provided between the superconducting portion 121 and a ground potential (the ground). The superconducting portion 122 is connected to the ground potential.

In the dc SQUID structure, it is possible to control the Josephson energy due to the Josephson junction by the flux inside the dc SQUID (Y. Makhlin et al., Rev. Mod. Phys. 73, 357 (2001)). The resonator 12 can oscillate according to the change of the flux inside the loop 12a. Multiple modes exist in the oscillation of the resonator 12. For example, the multiple modes include a first mode and a second mode; and the resonator 12 oscillates at a third frequency f3 near a first resonant frequency in the first mode, and oscillates at a fourth frequency f4 near a second resonant frequency in the second mode.

The electromagnetic wave application portion 11 applies an electromagnetic wave to the resonator 12. An external current for exciting the modes of the dc SQUID (an external current for exciting the dc SQUID) flows in the electromagnetic wave application portion 11. In other words, a varying magnetic field is generated by a high frequency current flowing in the electromagnetic wave application portion 11. Thereby, the electromagnetic wave application portion 11 can control the flux inside the dc SQUID (inside the loop 12a).

For example, the electromagnetic wave application portion 11 modulates the flux inside the resonator 12 (inside the dc SQUID) by applying, to the resonator 12, an electromagnetic wave (a first electromagnetic wave) having a frequency component of a first frequency f1. Thereby, the first mode is excited; and the resonator 12 oscillates at the third frequency f3 near the first resonant frequency.

The third frequency is equal to a half value f1/2 of the first frequency f1. In this specification, “the third frequency is equal to a half value (half) of the first frequency” includes the case where the third frequency and the half value of the first frequency are different within the range of the fluctuation of the measurement.

Or, the electromagnetic wave application portion 11 modulates the flux inside the resonator 12 by applying, to the resonator 12, an electromagnetic wave (a second electromagnetic wave) having a frequency component of the first frequency f1 and a frequency component of a second frequency f2. Thereby, the first mode and the second mode are excited; and the resonator 12 oscillates at the third frequency f3 near the first resonant frequency and the fourth frequency f4 near the second resonant frequency.

The fourth frequency is equal to the sum f2+f3 of the second frequency f2 and the third frequency f3. In this specification, “the fourth frequency is equal to the sum of the second frequency and the third frequency” includes the case where the fourth frequency and the sum of the second frequency and the third frequency are different within the range of the fluctuation of the measurement.

The conductive portion 30 transmits an electromagnetic wave that is generated by the oscillation of the resonator 12 and has passed through the filter 20. For example, the conductive portion 30 is a read line and is electrically connected to a measuring device, etc. Thereby, the electromagnetic wave that propagates from the resonator 12 via the filter 20 can be measured.

The filter 20 is provided between the resonator 12 and the conductive portion 30 in the circuit diagram illustrating the oscillation device 100. As illustrated in FIG. 1, the filter 20 has capacitive coupling with the resonator 12 and the conductive portion 30. The filter 20 is capacitively coupled with the resonator 12 at a first position 201 of the filter 20 and has capacitive coupling with the conductive portion 30 at a second position 202 that is different from the first position 201. In the example, the first position 201 and the second position 202 are end portions of the filter 20. The first position 201 and the second position 202 are not limited to end portions of a filter.

For example, the end portion at the first position 201 of the filter 20 and an end portion 123 of the resonator 12 (the waveguide 12b) are arranged to oppose each other. A capacitor C1 is provided between the end portion 123 and the end portion at the first position 201. Similarly, the end portion at the second position 202 of the filter 20 and an end portion 301 of the conductive portion 30 are arranged to oppose each other. A capacitor C2 is provided between the end portion 301 and the end portion at the second position 202.

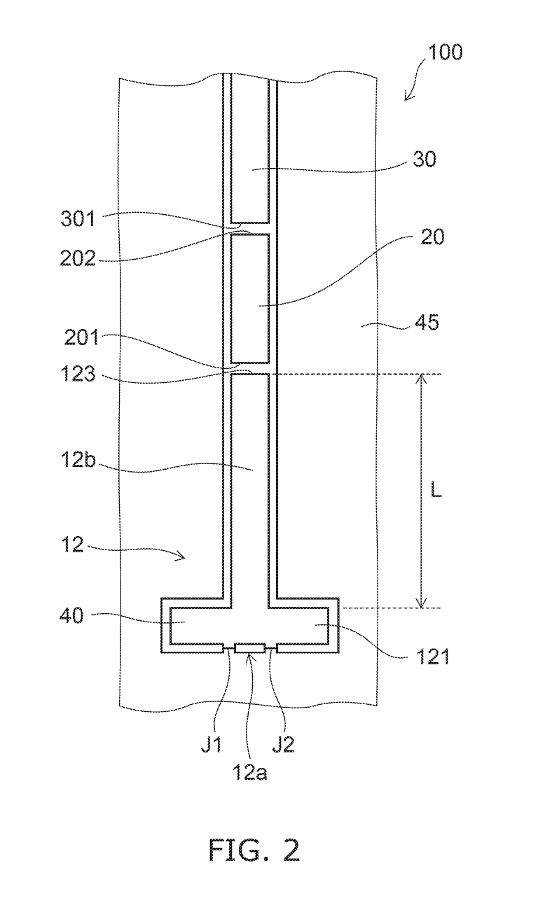

The filter 20 is a filter having frequency characteristics. The transmittance of the filter 20 for the fourth frequency f4 is higher than the transmittance of the filter 20 for the third frequency f3. For example, the filter 20 transmits the electromagnetic wave due to the second mode but does not transmit the electromagnetic wave due to the first mode. Such a filter 20 may include, for example, a λ/2 waveguide resonator for the electromagnetic wave of the fourth frequency f4. In other words, the length of the filter 20 (the length of the waveguide of the filter 20) is not shorter than 0.4 times and not longer than 0.6 times, and desirably 0.5 times, the wavelength inside the waveguide of the electromagnetic wave of the fourth frequency f4. In the example, the length of the waveguide of the filter 20 is the distance from the end portion at the first position 201 of the filter 20 to the end portion at the second position 202. However, the filter 20 may not have a straight line configuration such as that illustrated in FIG. 1 and FIG. 2 and may have a curved configuration or multiple straight portions. In such a case, the length of the waveguide is the length of the path inside the filter 20 from the end portion at the first position 201 to the end portion at the second position 202.

FIG. 2 is a plan view illustrating a portion of the oscillation device according to the embodiment.

As illustrated in FIG. 2, the resonator 12 (the oscillator 10), the filter 20, and the conductive portion 30 (the read line) are, for example, interconnects provided on a substrate 40. These interconnects include, for example, aluminum (Al), niobium (Nb), etc., and transition to superconductors by cooling. A conductive film that surrounds the interconnects recited above is provided on the substrate 40; and the conductive film 45 is connected to the ground potential. Thereby, the capacitor C0 shown in FIG. 1 is formed.

Interconnects are not provided between the end portion at the first position 201 of the filter 20 and the end portion 123 of the resonator 12. Thereby, the capacitor C1 shown in FIG. 1 is formed; and the filter 20 and the resonator 12 have capacitive coupling. Similarly interconnects are not provided between the end portion at the second position 202 of the filter 20 and the end portion 301 of the conductive portion 30. Thereby, the capacitor C2 is formed; and the filter 20 and the conductive portion 30 have capacitive coupling.

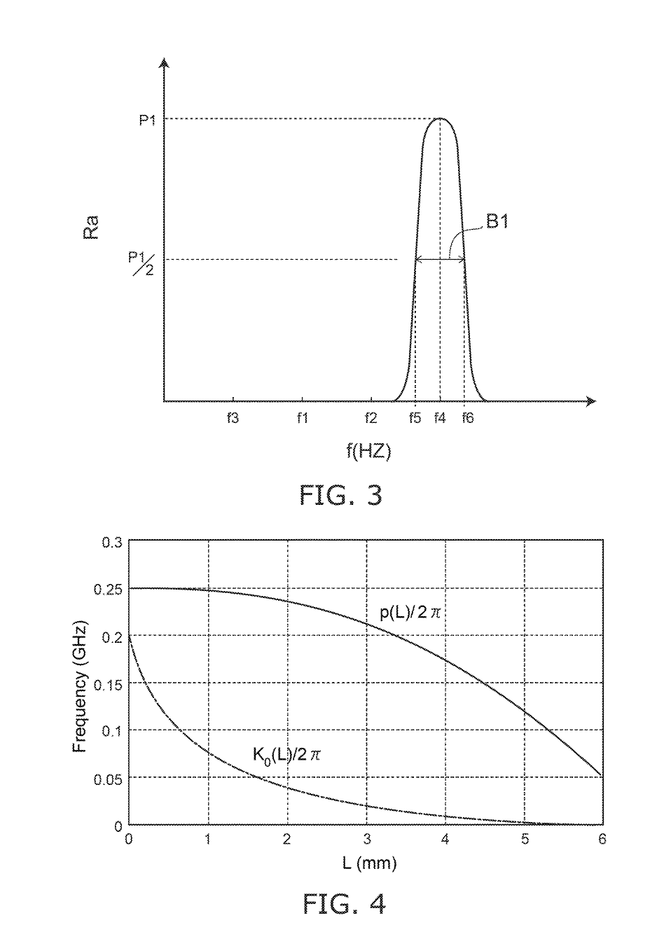

FIG. 3 is a graph illustrating the frequency characteristics of the filter of the oscillation device according to the embodiment.

The horizontal axis of FIG. 3 illustrates a frequency f (hertz (Hz)). The vertical axis of FIG. 3 illustrates a transmittance Ra of the filter 20. The transmittance Ra corresponds to the ratio of the amplitude of the electromagnetic wave output (applied) by the filter 20 to the conductive portion 30 to the amplitude of the electromagnetic wave input (applied) by the resonator 12 to the filter 20.

As illustrated in FIG. 3, the filter 20 is, for example, a band-pass filter and has a passband B1. In the passband B1, the transmittance Ra of the filter 20 has a peak (a maximum value P1). The passband B1 includes a fifth frequency f5, and a sixth frequency f6 that is higher than the fifth frequency f5. The transmittance of the filter 20 for the fifth frequency f5 is half (P1/2) of the peak value; and the transmittance of the filter 20 for the sixth frequency f6 is half (P1/2) of the peak value.

The fourth frequency f4 is included in the passband B1. For example, the fourth frequency f4 is in the range of the full width at half maximum of the frequency characteristics of the filter 20. In other words, the fourth frequency f4 is a frequency between the fifth frequency f5 and the sixth frequency f6. Thereby, the filter 20 transmits the electromagnetic wave due to the second mode.

On the other hand, the third frequency f3 is not included in the passband B1. For example, the third frequency f3 is lower than the fifth frequency f5. Or, the third frequency f3 is higher than the sixth frequency f6. Therefore, the filter 20 does not transmit the electromagnetic wave due to the first mode. Although the third frequency f3 is lower than the fourth frequency f4 in the example shown in FIG. 3, the embodiment is not limited to the example.

As described above, the first mode is excited by the first electromagnetic wave having the component of the first frequency f1. For example, the nonlinearity due to the Josephson junction may have a property in which the resonant frequency decreases as the number of photons inside the resonator increases. Therefore, when utilizing in quantum computing, it is desirable for the third frequency f3 that is equal to the half value f1/2 of the first frequency f1 to be not lower than the first resonant frequency. The first electromagnetic wave does not include a component of the second frequency f2; and the second mode substantially is not excited when the first electromagnetic wave is applied to the resonator 12.

On the other hand, it is desirable for the fourth frequency f4 (the sum of the second frequency f2 and the third frequency f3) to be equal to the second resonant frequency. In the embodiment, the difference (a first difference) between the fourth frequency f4 and the second resonant frequency is set to be narrower than the width of the passband B1. For example, the first difference is set to be within the range of the full width at half maximum of the frequency characteristics of the filter 20. In other words, the first difference is smaller than the difference between the fifth frequency f5 and the sixth frequency f6.

Thereby, the first mode and the second mode are excited by the electromagnetic wave having the components of the first frequency f1 and the second frequency f2.

The case is considered where the first mode is excited by the first electromagnetic wave having the component of the first frequency f1; and the resonator 12 oscillates at the third frequency f3. At this time, because the transmittance Ra of the filter 20 for the third frequency f3 is low, the electromagnetic wave of the third frequency f3 is not transmitted easily to the conductive portion 30 via the filter 20. Accordingly, when the first electromagnetic wave is applied to the resonator 12, the energy loss of the resonator 12 via the filter 20 and the conductive portion 30 is small.

On the other hand, the resonator 12 oscillates at the third and fourth frequencies f3 and f4 due to the second electromagnetic wave having the components of the first and second frequencies f1 and f2. At this time, because the transmittance Ra of the filter for the fourth frequency f4 is high, the electromagnetic wave of the fourth frequency f4 propagates to the conductive portion 30 via the filter 20. Accordingly, when the second electromagnetic wave is applied to the resonator 12, the energy loss of the resonator 12 is large compared to when the first electromagnetic wave is applied to the resonator 12.

In the oscillation device 100 according to the embodiment as described above, the filter 20 is provided between the resonator 12 and the conductive portion 30. Thereby, the loss can be adjusted by the control of the flux inside the dc SQUID.

For example, such an oscillation device 100 can be used in a quantum computer. For example, a combinatorial optimization problem can be solved by utilizing the oscillation phenomenon of a network of the multiple oscillation devices 100. In a quantum computer in which nonlinear oscillators are used, it is desirable to switch the reading ON and OFF so that the energy of the oscillator is not emitted to the outside as much as possible when calculating, and energy is extracted to the outside only when reading the calculation results.

On the other hand, in the case where the oscillator and the read line have capacitive coupling, it is difficult to switch the reading OFF completely when calculating. Therefore, there are cases where it is difficult to increase the ON/OFF ratio of the reading.

Conversely, in the case where the oscillation device 100 is used in the quantum computer, the loss when calculating can be reduced because the loss can be adjusted. According to the embodiment, for the nonlinear oscillator mounted in the superconducting circuit including the Josephson junction, the reading can be switched ON and OFF; and the loss of the oscillator when OFF can be extremely small.

The reading (the measuring) of the oscillation state of the oscillation device will now be described.

As described above, multiple modes exist in the resonator 12. Hereinbelow, the mode of the lowest resonant frequency is called the fundamental mode; and the other modes are called higher order modes. The higher order modes are numbered first-order, second-order, . . . , in order from the lower resonant frequencies.

The first mode and the second mode described above each are obtained by being selected arbitrarily from the fundamental mode and the higher order modes. For example, the first mode described above may be set to be the fundamental mode; and the second mode described above may be set to be the first-order mode.

The resonator 12 recited above has nonlinearity called the Kerr effect due to the Josephson junction. By modulating the Josephson energy by changing the flux inside the dc SQUID by using a frequency (e.g., corresponding to the first frequency f1) that is about 2 times the resonant frequency of the fundamental mode (e.g., corresponding to the first resonant frequency), the fundamental mode is parametrically excited; and oscillation occurs.

Because of the nonlinearity due to the Josephson junction, an interaction described by the following Hamiltonian exists between the fundamental mode and the higher order modes (displayed using a rotating coordinate system in which the fundamental mode is the oscillation angular frequency (the half value of the parametric excitation angular frequency), and the higher order modes are resonance angular frequencies of the oscillation angular frequency).

$${H}_{int} = {\sum }_{n = 1} {E}_{int}^{( n )} ( {a}_{0}^{†} {a}_{n} {e}^{- i ( {ω}_{n} - {ω}_{p} / 2 )} {a}_{n}^{†} {a}_{0} {e}^{i ( {ω}_{n} - {ω}_{p} / 2 )} ) \qquad [ Formula 1 ]$$

Here, a₀ is the annihilation operator of the fundamental mode, and aₙ is the annihilation operator of the nth-order mode. The coefficient E⁽ⁿ⁾ᵢₙₜ is the coefficient of the interaction between the fundamental mode and the nth-order mode and is proportional to the Josephson energy of the dc SQUID.

Normally, the difference (ωₙ−ωₚ/2) between the oscillation frequency ωₚ/2 (near a resonance angular frequency ω₀ of the fundamental mode) and a resonance angular frequency ωₙ of the nth-order mode is sufficiently large. Therefore, because of the fast oscillating factors:

$${e}^{\pm i ( {ω}_{n} - {ω}_{p} / 2 )} , \qquad [ Formula 2 ]$$

the interactions recited above can be ignored; and the higher order modes are not excited. However, if the flux inside the dc SQUID is modulated using an angular frequency (e.g., corresponding to the second frequency f2) equal to the angular frequency difference (ωₙ−ωₚ/2), the Josephson energy is modulated at the angular frequency; the fast oscillating factors inside the Hamiltonian recited above cancel; and energy conversion occurs from the fundamental mode to the nth-order mode. As a result, an electromagnetic wave of the angular frequency ωₙ (e.g., corresponding to the fourth frequency f4) is generated.

Therefore, the resonator 12 is coupled to the read line (the conductive portion 30) via the filter 20 transmitting the electromagnetic wave of the angular frequency ωₙ; and the state of the generated electromagnetic wave of the angular frequency ωₙ is measured. The state of the fundamental mode can be read by the measurement. On the other hand, the fundamental mode cannot pass through the filter 20; therefore, the energy of the fundamental mode is not emitted to the outside as long as there is no modulation at the angular frequency (ωₙ−ωₚ/2).

As described above, the loss of the fundamental mode when calculating can be extremely small by disposing, between the resonator 12 and the read line, the filter that transmits the nth-order mode of the resonator 12 but does not transmit the fundamental mode. When reading, a modulation at a frequency corresponding to the difference between the oscillation frequency and the resonant frequency of the nth-order mode is applied to the flux inside the dc SQUID of the oscillator. Thereby, the energy of the fundamental mode is converted into the nth-order mode; and the generated electromagnetic wave of the nth-order mode is measured by being extracted to the read line via the filter. Accordingly, the state of the fundamental mode is read. Thus, a large ON/OFF ratio can be realized; and the loss of the fundamental mode when OFF can be extremely small.

As described in reference to FIG. 3, it is taken that the setting of the frequencies recited above is performed with a precision that is about the same as that of the bandwidth (the passband B1) of the filter 20.

The state read method according to the embodiment is performed merely by disposing the filter 20 which is a passive element between the resonator 12 and the read line. In this state read method, the dc SQUID originally there for the parametric excitation is utilized as-is; and the modulation necessary for the reading can be performed. Therefore, the advantage is provided of being simpler than a method that uses a read line including a dc SQUID.

An example that uses the circuit shown in FIG. 1 will now be described.

Here, the first-order mode is used as the higher order mode used for reading.

When the Josephson energy of the dc SQUID in which the flux is modulated by the external current for exciting the dc SQUID is

Eⱼ(t)=Eⱼ⁽⁰⁾+Eₚ⁽⁰⁾cos ωₚt+Eᵣ⁽⁰⁾cos(ω₃−ωₚ/2)t [Formula 3],

the Hamiltonian of the nonlinear oscillator is roughly as follows.

$$H = ℏΔ {a}_{0}^{†} {a}_{0} - {\sum }_{n = 0} ℏ \frac{{K}_{n}}{2} {a}_{n}^{†2} {a}_{n}^{ 2} + ℏ \frac{p}{2} ( {a}_{0}^{†2} + {a}_{0}^{ 2} ) + ℏ {g}_{r} ( {a}_{0}^{†} {a}_{1} + {a}_{1}^{†} {a}_{0} ) \qquad [ Formula 4 ]$$

Here,

Δ=ω₃−ω₀/2 [Formula 5]

is the detuning of the fundamental mode for parametric excitation.

Kₙ is the Kerr coefficient of each mode and is represented by the following formula.

$${K}_{n} = \frac{{E}_{j}^{( 0 )}}{2 ℏ} {( \frac{ℏ}{2 {ω}_{n} {α}_{n}} )}^{2} {cos}^{4} ( {k}_{n} L ) \qquad [ Formula 6 ]$$

p is the parametric excitation amplitude and is represented by the following formula.

$$p = \frac{{E}_{p}^{( 0 )}}{2 ℏ} \frac{ℏ}{2 {ω}_{0} {α}_{0}} {cos}^{2} ( {k}_{0} L ) \qquad [ Formula 7 ]$$

gᵣ is the coupling coefficient between the fundamental mode and the first-order mode and is represented by the following formula.

$${g}_{r} = \frac{{E}_{r}^{( 0 )}}{2 ℏ} \sqrt{\frac{ℏ}{2 {ω}_{0} {α}_{0}} \frac{ℏ}{2 {ω}_{1} {α}_{1}}} cos ( {k}_{0} L ) cos ( {k}_{1} L ) \qquad [ Formula 8 ]$$

αₙ is a constant and is represented by the following formula.

$${α}_{n} = {φ}_{0}^{2} [ {C}_{j} {cos}^{2} ( {k}_{n} L ) + \frac{{C}_{w} L}{2} ( 1 + \frac{sin ( 2 {k}_{n} L )}{2 {k}_{n} L} ) ] \qquad [ Formula 9 ]$$

Here, φ₀ is the flux quantum divided by 2π and is represented by the following formula.

φ₀=h/(2e) [Formula 10]

kₙ is the wave number of each mode inside the waveguide and satisfies

$$\begin{matrix}{ω}_{n} / {k}_{n} = 1 / \sqrt{{L}_{w} {C}_{w}} & [ Formula 11 ] \\ and & \\ tan ( {k}_{n} L ) = {Z}_{w} ( - {C}_{j} {ω}_{n} + \frac{I}{{L}_{j} {ω}_{n}} ) & [ Formula 12 ]\end{matrix}$$

Here, C_{w} and L_{w} are the capacitance and the inductance per unit length of the waveguide.

$${Z}_{w} = \sqrt{\frac{{L}_{w}}{{C}_{w}}} \qquad [ Formula 13 ]$$

is the characteristic inductance of the waveguide.

Lⱼ=φ₀²/Eⱼ⁽⁰⁾ [Formula 14]

is the Josephson inductance of the dc SQUID.

Specific values of the parameters will now be selected and described.

As typical values, C_{w}=150 (femtofarad/millimeter (fF/mm)), Z_{w}=50 (ohms (Q)), and ω₀/2π=5 (gigahertz (GHz)) are used. It is taken that

Eₚ⁽⁰⁾=E₀⁽⁰⁾=0.2Eⱼ⁽⁰⁾ [Formula 15].

Then, the remaining parameters are determined by only Cⱼ and L. The case will now be described where Cⱼ is designed to be a relatively large value of 100 fF in a first example; and Cⱼ is designed to be a relatively small value of 10 fF in a second example.

### First Example

Here, Cⱼ is set to the relatively large value of 100 fF. At this time, K₀ and p are represented as functions of L as in FIG. 4.

FIG. 4 is a graph illustrating calculation results of the Kerr coefficient and the parametric excitation amplitude of the first example.

It is undesirable for L to be a value near 6 mm because K₀ becomes small and the nonlinearity is small. It is undesirable as an oscillator for L to be near zero because it is difficult to set p to be large compared to K₀. Therefore, in this case, it is desirable for L to be not shorter than 1 mm and not longer than 4 mm.

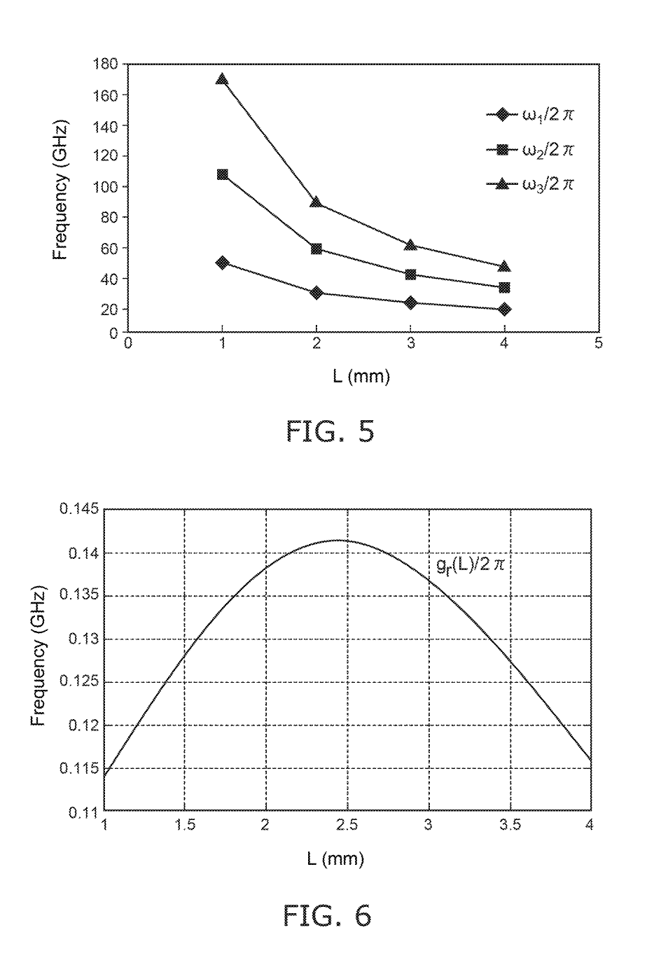

FIG. 5 is a graph illustrating calculation results of the resonant frequencies of the higher order modes of the first example.

FIG. 5 shows the resonant frequencies of the higher order modes in the case where L is 1 mm, 2 mm, 3 mm, or 4 mm. It can be seen that the resonant frequencies of the higher order modes are shifted greatly from the resonant frequency of the fundamental mode of 5 GHz. It can be seen that the difference between the resonant frequency of one of the higher order modes and the resonant frequency of another of the higher order modes is 10 GHz or more.

FIG. 6 is a graph illustrating calculation results of the coupling coefficient of the fundamental mode and the first-order mode of the first example. FIG. 6 shows the L dependence of gᵣ. gᵣ has a maximum value at the vicinity where L=2.5 mm. The value of gᵣ is sufficiently large and is such that gᵣ/2π≈140 MHz. Thereby, the fundamental mode can be converted efficiently to the first-order mode by the modulation.

A filter that transmits only the first-order mode will now be described. As an example, the case is considered where gᵣ has a maximum at L=2.5 mm. At this time, the resonant frequency of the first-order mode is 22.6 GHz. Thereby, a filter that transmits 22.6 GHz is disposed between the oscillator and the read line. Such a filter can be mounted using a λ/2 waveguide resonator having a resonant frequency of the fundamental mode of 22.6 GHz. For example, the capacitance and the characteristic impedance per unit length of the waveguide are set to be the same as those recited above, i.e., 150 fF/mm and 50Ω, respectively. In such a case, because the wavelength of 22.6 GHz is 5.90 mm, it is sufficient to set the length of the resonator to 2.95 mm which is half of 5.90 mm. Because the resonant frequency of the fundamental mode of the oscillator is 5 GHz, the electromagnetic wave due to the fundamental mode cannot pass through the filter.

### Second Example

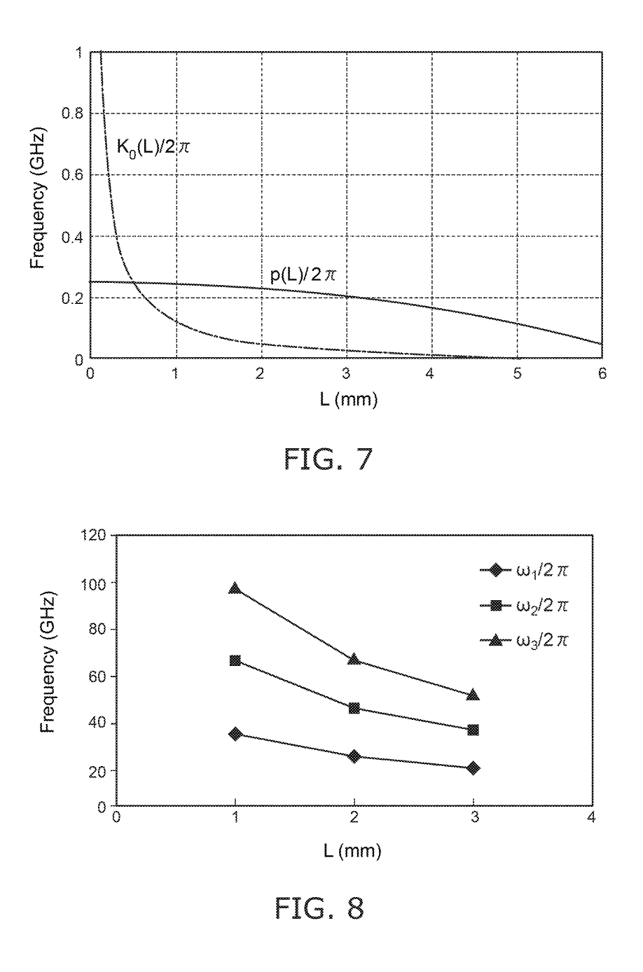

Here, Cⱼ is set to the relatively small value of 10 fF. At this time, K₀ and p are represented as a function of L as in FIG. 7.

FIG. 7 is a graph illustrating calculation results of the Kerr coefficient and the parametric excitation amplitude of the second example.

It is undesirable for L to be a value near 6 mm because K₀ becomes small and the nonlinearity is small. It is undesirable as an oscillator for L to be 1 mm or less because it is difficult to set p to be large compared to K₀. Therefore, in this case, it is desirable for L to be 2 mm to 4 mm.

FIG. 8 is a graph illustrating calculation results of the resonant frequencies of the higher order modes of the second example.

FIG. 8 shows the resonant frequencies of the higher order modes in the case where L is 2 mm, 3 mm, or 4 mm. It can be seen that the resonant frequencies of the higher order modes are greatly shifted from the resonant frequency of the fundamental mode of 5 GHz. It can be seen that the difference between the resonant frequency of one of the higher order modes and the resonant frequency of another of the higher order modes is 10 GHz or more.

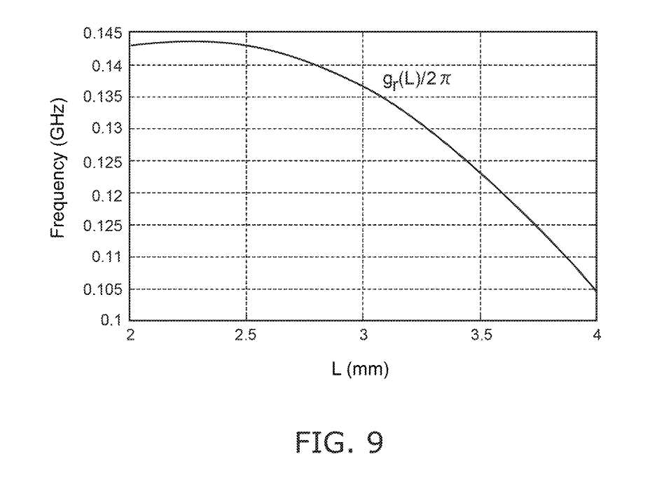

FIG. 9 is a graph illustrating calculation results of the coupling coefficient of the fundamental mode and the first-order mode of the second example. FIG. 9 shows the L-dependence of gᵣ. gᵣ has a maximum value at the vicinity where L=2.3 mm. The value of gᵣ is sufficiently large and is such that gᵣ/2π≈145 MHz. Thereby, the fundamental mode can be converted efficiently to the first-order mode by the modulation.

A filter that transmits only the first-order mode will now be described. As an example, the case is considered where gᵣ has a maximum when L=2.3 mm. In such a case, the resonant frequency of the first-order mode is 29.1 GHz. Thereby, a filter that transmits 29.1 GHz is disposed between the oscillator and the read line. Such a filter can be mounted using a λ/2 waveguide resonator having a resonant frequency of the fundamental mode of 29.1 GHz. The capacitance and the characteristic impedance per unit length of the waveguide are set to be the same as those recited above, i.e., 150 fF/mm and 50Ω, respectively. In such a case, because the wavelength of 29.1 GHz is 4.58 mm, it is sufficient to set the length of the resonator to be 2.29 mm which is half of 4.58 mm. Because the resonant frequency of the fundamental mode of the oscillator is 5 GHz, the electromagnetic wave due to the fundamental mode cannot pass through the filter.

### Third Example

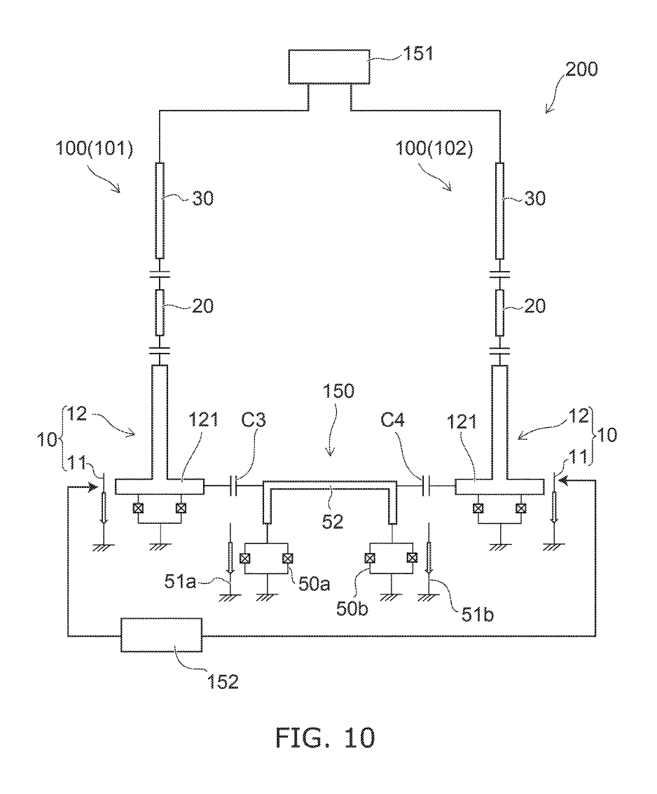

FIG. 10 is a schematic view illustrating a computing device according to the embodiment.

As illustrated in FIG. 10, the computing device 200 (the quantum computing device) includes a coupled resonator 150 and the multiple oscillation devices 100. In the example, a first oscillation device 101 and a second oscillation device 102 are provided as the multiple oscillation devices 100. The first oscillation device 101 and the second oscillation device are coupled via the coupled resonator 150.

The coupled resonator 150 includes an interconnect portion 52 (a superconducting portion), a resonator 50a, a resonator 50b, an electromagnetic wave application portion 51a, and an electromagnetic wave application portion 51b. The interconnect portion 52 is a waveguide.

The resonator 50a and the resonator 50b each have dc SQUID structures. In other words, each of the resonators is a superconducting circuit having a loop configuration formed of two Josephson junctions. In the circuit, the resonator 50a is provided between the ground potential and one end of the interconnect portion 52; and the resonator 50b is provided between the ground potential and another end of the interconnect portion 52.

The electromagnetic wave application portion 51a can modulate the flux inside the resonator 50a (the dc SQUID) by a current. Similarly, the electromagnetic wave application portion 51b can modulate the flux inside the resonator 50b (the dc SQUID) by a current.

The resonator 12 (the superconducting portion 121) of the first oscillation device 101 has capacitive coupling with the interconnect portion 52 of the coupled resonator 150 by a capacitor C3. Similarly, the resonator 12 (the superconducting portion 121) of the second oscillation device 102 has capacitive coupling with the interconnect portion 52 of the coupled resonator 150 by a capacitor C4.

Thus, in the computing device 200 according to the embodiment, each of the multiple oscillation devices 100 has capacitive coupling with a coupled resonator terminated with a dc SQUID. Thereby, the oscillation devices 100 are coupled to each other via the coupled resonators; and a network of the oscillation devices 100 is formed.

Although the case is illustrated in FIG. 10 where two oscillation devices 100 are coupled, three or more oscillation devices 100 may be provided in the embodiment. In such a case, it is sufficient to increase the number of arms of the oscillation devices 100 and to provide the coupled resonators 150 between the multiple oscillation devices 100.

As illustrated in FIG. 10, the computing device 200 is electrically connected to a measuring device 151 and a controller 152. The controller 152 individually controls the parameters (called the bifurcation parameters) of the systems of each of the oscillation devices 100. For example, the controller 152 controls the current of the electromagnetic wave application portion 11 of each of the oscillation devices 100.

The measuring device 151 is electrically connected to the conductive portion 30 (the read line) of each of the oscillation devices 100. The measuring device 151 measures the output of each of the oscillation devices 100 via the conductive portion 30. The computing device 200 can obtain the calculation results from the measurement results. For example, the measuring device 151 measures the parity of the phase of the electric field amplitude.

For example, the computing device 200 is utilized to solve a combinatorial optimization problem.

In the case where the oscillation device 100 is solitary, it is possible to superimpose discriminable quantum states by bifurcating one quantum state by using a quantum adiabatic change having the parameters (the bifurcation parameters) of the system as control parameters. The loss of the oscillation device 100 when calculating is small enough that the effects of the loss can be ignored. For example, the oscillation device 100 generates quantum-mechanical superimposition of two oscillation states while gradually increasing the parametric excitation amplitude p (the bifurcation parameter of the oscillation device 100) from zero by using the vacuum state as the initial state.

The computing device 200 that multiply uses such oscillation devices 100 finds the optimal solution by utilizing a quantum adiabatic change having a vacuum as the initial state. In the calculation, the coupling between the oscillation devices 100 is set to match the problem to be solved. For example, the Hamiltonian of the network of the oscillation devices 100 can be considered using the Ising model as an example. The setting of the coupling between the oscillation devices 100 corresponds to the setting of coupling constants between Ising spins.

After setting the coupling, the bifurcation parameter is changed gradually. At the start of the calculation, the bifurcation parameter is zero; and the vacuum state which is the initial state is the base state of the entire system. As the bifurcation parameter is changed sufficiently slowly, the state of the entire system changes to the base state of the final Hamiltonian according to the quantum adiabatic theorem. Here, in the case where the bifurcation parameter is sufficiently large, the nonlinear terms (the parametric amplification and the Kerr effect) are dominant; the condition is reached in which the oscillation amplitude is about the same for each of the oscillation devices; and only the phases are different. Then, the calculation results are obtained from the measurement results by measuring the phases from the oscillation devices 100.

Thus, the combinatorial optimization problem can be solved by utilizing the oscillation phenomenon (the bifurcation phenomenon) and the quantum effect by using a network of the oscillation devices 100.

It is also possible to directly couple two oscillation devices 100 via a capacitor. However, in the case where the two oscillation devices 100 are directly coupled, the degrees of freedom of the arrangement of the oscillation devices 100 is low; and it is difficult to modify the coupling constant. Therefore, in the example of FIG. 10, the oscillation devices 100 are coupled to each other by the coupled resonator 150. Thereby, the degrees of freedom of the arrangement increase. The modification of the coupling constant according to the problem to be solved is easy by adjusting the detuning of the coupled resonator 150 and/or the coupling strength between the coupled resonator 150 and the oscillation devices 100.

The embodiments include, for example, the following configurations.

### (Configuration 1)

An oscillation device, comprising:

a resonator including a Josephson junction;

an electromagnetic wave application portion applying a first electromagnetic wave and a second electromagnetic wave to the resonator, the first electromagnetic wave having a component of a first frequency, the second electromagnetic wave having a component of the first frequency and a component of a second frequency;

a filter; and

a conductive portion transmitting an electromagnetic wave passing through the filter,

the resonator oscillating at a third frequency due to the first electromagnetic wave and oscillating at the third frequency and a fourth frequency due to the second electromagnetic wave, a transmittance of the filter for the fourth frequency being higher than a transmittance of the filter for the third frequency.

### (Configuration 2)

The oscillation device according to configuration 1, wherein

the third frequency is equal to half of the first frequency, and

the fourth frequency is equal to the sum of the second frequency and the third frequency.

### (Configuration 3)

The oscillation device according to configuration 1 or 2, wherein

a transmittance of the filter for a fifth frequency is half of a peak value of the transmittance of the filter, the fifth frequency being included in one passband of the filter,

a transmittance of the filter for a sixth frequency is half of the peak value, the sixth frequency being included in the passband and being higher than the fifth frequency,

the fourth frequency is between the fifth frequency and the sixth frequency, and

the third frequency is lower than the fifth frequency or higher than the sixth frequency.

### (Configuration 4)

The oscillation device according to one of configurations 1 to 3, wherein the filter has capacitive coupling with the resonator at a first position of the filter, and capacitive coupling with the conductive portion at a second position of the filter, the second position being different from the first position.

### (Configuration 5)

The oscillation device according to one of configurations 1 to 4, wherein a resonant frequency of the resonator nearest the third frequency is not higher than the third frequency.

### (Configuration 6)

The oscillation device according to one of configurations 1 to 5, wherein the electromagnetic wave application portion modulates flux inside a loop included in the resonator.

### (Configuration 7)

The oscillation device according to one of configurations 1 to 6, wherein

the filter includes a waveguide, and

a length of the waveguide is not shorter than 0.4 times and not longer than 0.6 times a wavelength inside the waveguide of an electromagnetic wave of the fourth frequency.

### (Configuration 8)

The oscillation device according to one of configurations 1 to 7, wherein

the resonator includes a plurality of resonant frequencies, and

a resonant frequency of the resonator nearest the third frequency is the lowest of the plurality of resonant frequencies.

### (Configuration 9)

A computing device, comprising a plurality of the oscillation devices according to any one of configurations 1 to 8,

the plurality of oscillation devices including a first oscillation device and a second oscillation device,

the first oscillation device and the second oscillation device being coupled to each other.

### (Configuration 10)

The computing device according to configuration 9, further comprising a coupled resonator including an interconnect portion,

the first oscillation device and the second oscillation device being coupled via the coupled resonator.

### (Configuration 11)

The computing device according to configuration 10, wherein the coupled resonator includes a Josephson junction provided between a ground potential and one end of the interconnect portion.

### (Configuration 12)

The computing device according to configuration 11, wherein the coupled resonator further includes an electromagnetic wave application portion modulating flux inside a loop included in the coupled resonator.

### (Configuration 13)

The computing device according to one of configurations 10 to 12, wherein the first oscillation device has capacitive coupling with the interconnect portion of the coupled resonator.

### (Configuration 14)

A measurement method of an oscillation state of a resonator including a loop including a Josephson junction, the resonator oscillating at a second frequency by modulating flux inside the loop at a first frequency, the second frequency being equal to a half value of the first frequency, the method comprising:

causing the resonator to oscillate at a fourth frequency by applying a modulation at a third frequency to the flux of the loop in addition to the modulation at the first frequency, the fourth frequency being equal to the sum of the second frequency and the third frequency;

extracting, to a read line, an electromagnetic wave of the fourth frequency via a filter transmitting the electromagnetic wave of the fourth frequency; and

measuring the electromagnetic wave of the fourth frequency in the read line.

### (Configuration 15)

A measurement method of an oscillation state of a resonator, the resonator including a Josephson junction, the method comprising:

applying, to the resonator, a first electromagnetic wave having a component of a first frequency;

applying a second electromagnetic wave to the resonator, the second electromagnetic wave having a component of the first frequency and a component of a second frequency; and

measuring an electromagnetic wave transmitted via a filter from the resonator,

the resonator oscillating at a third frequency due to the first electromagnetic wave and oscillating at the third frequency and a fourth resonant frequency due to the second electromagnetic wave,

a transmittance of the filter for the fourth frequency being higher than a transmittance of the filter for the third frequency.

### (Configuration 16)

The method according to configuration 15, wherein

the third frequency is equal to half of the first frequency, and

the fourth frequency is equal to the sum of the second frequency and the third frequency.

### (Configuration 17)

The method according to configuration 15 or 16, wherein

a transmittance of the filter for a fifth frequency is half of a peak value of the transmittance of the filter, the fifth frequency being included in one passband of the filter,

a transmittance of the filter for a sixth frequency is half of the peak value, the sixth frequency being included in the passband and being higher than the fifth frequency,

the fourth frequency is between the fifth frequency and the sixth frequency, and

the third frequency is lower than the fifth frequency or higher than the sixth frequency.

### (Configuration 18)

The method according to one of configurations 15 to 17, wherein the filter has capacitive coupling with the resonator at a first position of the filter, and has capacitive coupling with a conductive portion at a second position of the filter, the second position being different from the first position.

In the embodiment, the state of being electrically connected includes not only the state in which multiple conductors are in direct contact, but also the case where the multiple conductors are connected via another conductor. The state of being electrically connected includes the case where multiple conductors are connected via an element having a function such as switching, amplification, etc.

According to the embodiments, an oscillation device, a computing device, and a measurement method can be provided in which the loss can be adjusted.

Hereinabove, embodiments of the invention are described with reference to specific examples. However, the invention is not limited to these specific examples. For example, one skilled in the art may similarly practice the invention by appropriately selecting specific configurations of components such as the resonator, the electromagnetic wave application portion, the filter, the conductive portion, etc., from known art; and such practice is within the scope of the invention to the extent that similar effects can be obtained.

Further, any two or more components of the specific examples may be combined within the extent of technical feasibility and are included in the scope of the invention to the extent that the purport of the invention is included.

Moreover, all oscillation devices, computing devices, and measurement methods practicable by an appropriate design modification by one skilled in the art based on the oscillation devices, the computing devices, and the measurement methods described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An oscillation device, comprising:
a resonator including a Josephson junction;
an electromagnetic wave application portion applying a first electromagnetic wave and a second electromagnetic wave to the resonator, the first electromagnetic wave having a component of a first frequency, the second electromagnetic wave having a component of the first frequency and a component of a second frequency;
a filter; and
a conductive portion transmitting an electromagnetic wave passing through the filter,
the resonator oscillating at a third frequency due to the first electromagnetic wave and oscillating at the third frequency and a fourth frequency due to the second electromagnetic wave, a transmittance of the filter for the fourth frequency being higher than a transmittance of the filter for the third frequency.

2. The oscillation device according to claim 1, wherein
the third frequency is equal to half of the first frequency, and
the fourth frequency is equal to the sum of the second frequency and the third frequency.

3. The oscillation device according to claim 1, wherein
a transmittance of the filter for a fifth frequency is half of a peak value of the transmittance of the filter, the fifth frequency being included in one passband of the filter,
a transmittance of the filter for a sixth frequency is half of the peak value, the sixth frequency being included in the passband and being higher than the fifth frequency,
the fourth frequency is between the fifth frequency and the sixth frequency, and
the third frequency is lower than the fifth frequency or higher than the sixth frequency.

4. The oscillation device according to claim 1, wherein the filter has capacitive coupling with the resonator at a first position of the filter, and capacitive coupling with the conductive portion at a second position of the filter, the second position being different from the first position.

5. The oscillation device according to claim 1, wherein a resonant frequency of the resonator nearest the third frequency is not higher than the third frequency.

6. The oscillation device according to claim 1, wherein the electromagnetic wave application portion modulates flux inside a loop included in the resonator.

7. The oscillation device according to claim 1, wherein
the filter includes a waveguide, and
a length of the waveguide is not shorter than 0.4 times and not longer than 0.6 times a wavelength inside the waveguide of an electromagnetic wave of the fourth frequency.

8. The oscillation device according to claim 1, wherein
the resonator includes a plurality of resonant frequencies, and
a resonant frequency of the resonator nearest the third frequency is the lowest of the plurality of resonant frequencies.

9. A computing device, comprising a plurality of the oscillation devices according to claim 1,
the plurality of oscillation devices including a first oscillation device and a second oscillation device,
the first oscillation device and the second oscillation device being coupled to each other.

10. The computing device according to claim 9, further comprising a coupled resonator including an interconnect portion,
the first oscillation device and the second oscillation device being coupled via the coupled resonator.

11. The computing device according to claim 10, wherein the coupled resonator includes a Josephson junction provided between a ground potential and one end of the interconnect portion.

12. The computing device according to claim 11, wherein the coupled resonator further includes an electromagnetic wave application portion modulating flux inside a loop included in the coupled resonator.

13. The computing device according to claim 10, wherein the first oscillation device has capacitive coupling with the interconnect portion of the coupled resonator.

14. A measurement method of an oscillation state of a resonator including a loop including a Josephson junction, the resonator oscillating at a second frequency by modulating flux inside the loop at a first frequency, the second frequency being equal to a half value of the first frequency, the method comprising:
causing the resonator to oscillate at a fourth frequency by applying a modulation at a third frequency to the flux of the loop in addition to the modulation at the first frequency, the fourth frequency being equal to the sum of the second frequency and the third frequency;
extracting, to a read line, an electromagnetic wave of the fourth frequency via a filter transmitting the electromagnetic wave of the fourth frequency; and
measuring the electromagnetic wave of the fourth frequency in the read line.

15. A measurement method of an oscillation state of a resonator, the resonator including a Josephson junction, the method comprising:
applying, to the resonator, a first electromagnetic wave having a component of a first frequency;
applying a second electromagnetic wave to the resonator, the second electromagnetic wave having a component of the first frequency and a component of a second frequency; and
measuring an electromagnetic wave transmitted via a filter from the resonator,
the resonator oscillating at a third frequency due to the first electromagnetic wave and oscillating at the third frequency and a fourth resonant frequency due to the second electromagnetic wave,
a transmittance of the filter for the fourth frequency being higher than a transmittance of the filter for the third frequency.

16. The method according to claim 15, wherein
the third frequency is equal to half of the first frequency, and
the fourth frequency is equal to the sum of the second frequency and the third frequency.

17. The method according to claim 15, wherein
a transmittance of the filter for a fifth frequency is half of a peak value of the transmittance of the filter, the fifth frequency being included in one passband of the filter,
a transmittance of the filter for a sixth frequency is half of the peak value, the sixth frequency being included in the passband and being higher than the fifth frequency,
the fourth frequency is between the fifth frequency and the sixth frequency, and
the third frequency is lower than the fifth frequency or higher than the sixth frequency.

18. The method according to claim 15, wherein the filter has capacitive coupling with the resonator at a first position of the filter, and has capacitive coupling with a conductive portion at a second position of the filter, the second position being different from the first position.
